(19) United States
(12) Patent Application Publication
(10) Pub. No.: US 2026/0293408 A1
(43) Pub. Date: Sep. 24, 2026

(54) ELECTRONIC DEVICE

(71) Applicants: Innolux Corporation, Miaoli County (TW); CARUX TECHNOLOGY PTE. LTD., SINGAPORE (SG)

(72) Inventors: Yu-Chia Huang, Miaoli County (TW); Tsung-Han Tsai, Miaoli County (TW); Yu-Hsuan Hsiao, Tainan (TW); Chih-Chang Chen, Tainan (TW); Li-Wei Sung, Tainan (TW)

(73) Assignees: Innolux Corporation, Miaoli County (TW); CARUX TECHNOLOGY PTE. LTD., SINGAPORE (SG)

(21) Appl. No.: 19/550,296

(22) Filed: Feb. 26, 2026

(30) Foreign Application Priority Data
Mar. 18, 2025 (CN) 202510319722.1

(51) Int. Cl. H10H 29/855; H10H 29/24

(52) U.S. Cl. CPC H10H 29/855; H10H 29/24; H10H 29/8552

(57) ABSTRACT

An electronic device includes a substrate, a plurality of light-emitting elements, a light-shielding layer, and a plurality of lens units. The light-emitting elements are disposed on the substrate. The light-shielding layer is disposed on the light-emitting elements and has a plurality of openings. The lens units are disposed on the light-shielding layer and disposed corresponding to the light emitting units. In a top view direction of the electronic device, each of the lens units has a geometric center, and one of the openings of the light-shielding layer is spaced from the geometric center of a corresponding one of the lens units by a distance.

### CROSS-REFERENCE TO RELATED APPLICATION

This application claims the priority benefit of China application serial no. 202510319722.1, filed on Mar. 18, 2025. The entirety of the above-mentioned patent application is hereby incorporated by reference herein and made a part of this specification.

### BACKGROUND

### Technical Field

The disclosure relates to an electronic device.

### Related Art

The development of head up display (HUD) technology brings more diverse application methods for display products. In some applications, it is required to display images in a specific viewing angle region. For example, in automotive display applications, it is usually required to provide clear display images in the viewing angle region where the driver is positioned. In addition, displaying images in a specific viewing angle region may also be used to implement other applications, such as privacy protection, three-dimensional display, or reducing the impact of reflective glare.

### SUMMARY

The disclosure provides an electronic device, which can provide display effects at specific viewing angles.

The electronic device of the disclosure includes a substrate, a plurality of light-emitting elements, a light-shielding layer, and a plurality of lens units. The light-emitting elements are disposed on the substrate. The light-shielding layer is disposed on the light-emitting elements and has a plurality of openings. The lens units are disposed on the light-shielding layer and disposed corresponding to the light emitting units. In a top view direction of the electronic device, each of the lens units has a geometric center, and one of the openings in the light-shielding layer is spaced from a corresponding one of the lens units by a distance.

### BRIEF DESCRIPTION OF THE DRAWINGS

FIG. 1 is a schematic view of an electronic device according to some embodiments of the disclosure.

FIG. 2 is a cross-sectional schematic view along a line I-I in FIG. 1.

FIG. 3 is a cross-sectional schematic view along a line II-II in FIG. 1.

FIG. 4 is a partial schematic view of the electronic device according to an embodiment of the disclosure.

FIG. 5 and FIG. 6 are used to illustrate another implementation of a single anisotropic light-emitting structure.

FIG. 7 and FIG. 8 are used to illustrate another implementation of a single anisotropic light-emitting structure.

FIG. 9 is a partial schematic view of the electronic device according to an embodiment of the disclosure.

FIG. 10 is a schematic view of the electronic device according to an embodiment of the disclosure.

FIG. 11 is a schematic view of the electronic device according to an embodiment of the disclosure.

FIG. 12 is a partial cross-sectional structural schematic view of the electronic device according to an embodiment of the disclosure.

FIG. 13 is a partial cross-sectional structural schematic view of the electronic device according to an embodiment of the disclosure.

### DESCRIPTION OF THE EMBODIMENTS

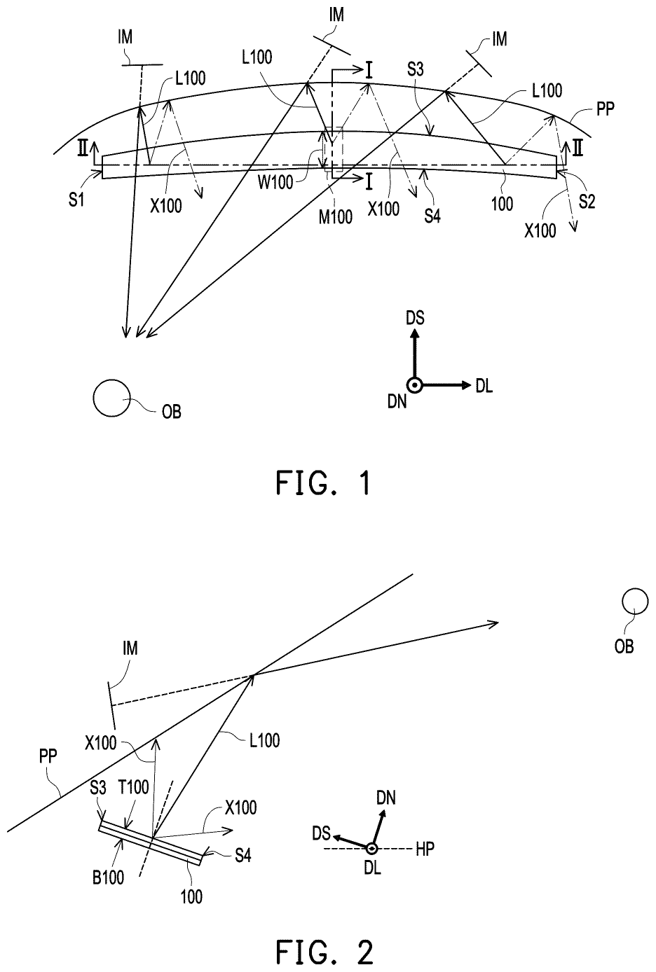

FIG. 1 is a schematic view of an electronic device according to some embodiments of this disclosure. An electronic device 100 in FIG. 1 may be disposed at one side of a projection screen PP and used to provide display light L100 toward the projection screen PP. The electronic device 100 is adapted to provide images, and a viewer OB and the projection screen PP may be located on opposite sides of the electronic device 100. For convenience of explanation, the side of the projection screen PP adjacent to the electronic device 100 may be referred to as an inner side, while the side away from the electronic device 100 and opposite to the inner side may be an outer side. The projection screen PP is a screen through which visible light may pass. Therefore, the viewer OB may see the environmental scenery on the outer side of the projection screen PP. Additionally, after the display light L100 illuminates the projection screen PP, the viewer OB may see a virtual image IM established on the outer side of the projection screen PP.

In FIG. 1, the electronic device 100 includes edges S1 to S4, and has an elongated contour that may define a long axis direction DL and a short axis direction DS. The edge S1 and the edge S2 of the electronic device 100 are on opposite sides in the long axis direction DL, while the edge S3 and the edge S4 of the electronic device 100 are on opposite sides in the short axis direction DS. The edge S3 is closer to the projection screen PP than the edge S4, and the edge S4 is closer to the viewer OB than the edge S3. Both the edge S3 and the edge S4 present curved or linear forms, and may have different radii of curvature. For example, the radius of curvature of the edge S3 may be smaller than the radius of curvature of the edge S4. As such, the distance between the edge S3 and the edge S4, which is a width W100 of the electronic device 100 in the short axis direction DS, is variable. For example, the width W100 of the electronic device 100 is wider at a middle portion M100 and becomes narrower toward the two sides at the edge S1 and the edge S2. In some embodiments, the electronic device 100 may be a continuous, integrated device. However, in other embodiments, the electronic device 100 may be formed by joining multiple independent devices.

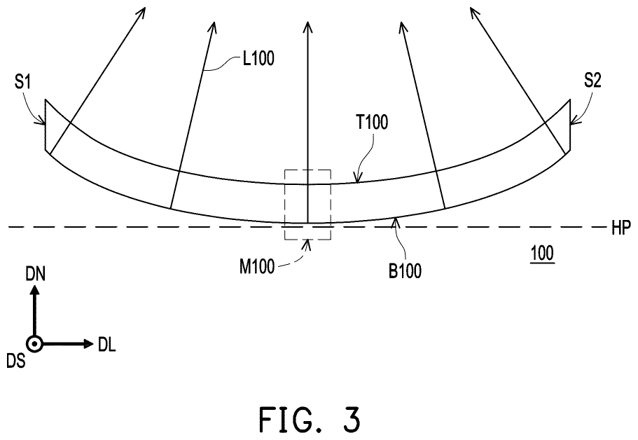

FIG. 2 is a cross-sectional schematic view along a line I-I in FIG. 1, and FIG. 3 is a cross-sectional schematic view along a line II-II in FIG. 1. As shown in FIG. 2 and FIG. 3, the outer contour of the electronic device 100 has a top surface T100 and a bottom surface B100, where FIG. 2 shows that the top surface T100 and the bottom surface B100 may be substantially parallel to each other in the short axis direction DS, and FIG. 3 shows that the top surface T100 and the bottom surface B100 may be in a curved state in the long axis direction DL. Therefore, the electronic device 100 is a curved or planar device. As shown in FIG. 3, with a horizontal plane HP as a reference plane, the orientation method of the electronic device 100 is such that the middle portion M100 of the electronic device 100 is concave with respect to the edge S1 and the edge S2. Therefore, from the viewing angle in FIG. 1, the edge S1 and the edge S2 on the two sides of the electronic device 100 are farther away from the paper surface compared to the middle portion M100. Additionally, in this document, the plane formed by the long axis direction DL and the short axis direction DS has a normal direction DN, and the normal direction DN is, for example, the extension direction of the normal of the middle portion M100 of the electronic device 100.

In some embodiments, as shown in FIG. 1, the projection screen PP generally conforms to the long axis direction DL of the electronic device 100 in a curved state, and as shown in FIG. 2, the projection screen PP appears inclined in the cross-section along the line I-I. As shown in FIG. 2, the projection screen PP and the electronic device 100 have different inclination angles with respect to the horizontal plane HP. The inclined projection screen PP intersects with the normal direction DN to allow the display light L100 to illuminate the projection screen PP and establish the virtual image IM visible to the observer OB. In some embodiments, the electronic device 100 may be installed in a vehicle, and the projection screen PP may be the windshield of the vehicle or an optical component with at least partial reflection function. In other words, the electronic device 100 may be a head-up display for vehicles, but the disclosure is not limited thereto. When the electronic device 100 is applied as a head-up display for vehicles, the horizontal plane HP may be considered as the plane where the vehicle body is located.

In some embodiments, among the light provided by the electronic device 100, a portion of light emitted toward a specific emission angular range may effectively establish the display light L100 for the virtual image IM, but portions of light traveling in other directions cannot be used to establish the virtual image IM and become stray light X100 (as shown in FIG. 1 and FIG. 2). For example, when representing the light distribution of the electronic device 100 in a polar coordinate system, the display light L100 that can effectively establish the virtual image IM mainly falls within a target region of the polar coordinate system. In some embodiments, this target region, for example, is located in the lower half of the polar coordinate system and has an arc contour with a central portion farther from the horizontal axis and both ends closer to the horizontal axis. Furthermore, to present the required light traveling angular range, in some embodiments, the light emitted by the electronic device 100 may have asymmetric light distribution (for example, the slopes at both ends of the light distribution curve at the vertex (maximum brightness location) are different) in the directions of an azimuth angle 270 degrees and an azimuth angle 225 degrees. The azimuth angles of 270 degrees and 225 degrees are merely for example, in other embodiments, the light emitted by the electronic device 100 may have asymmetric light distribution in the directions of two other different azimuth angles. Since the stray light X100 traveling at angles outside the target region may cause unwanted glare phenomena and may further interfere with the display light L100, resulting in degraded display effect, the electronic device 100 has adjustment means for regulating the light traveling angular range, so that compared with devices without adjustment means, the electronic device 100 has less stray light X100. The following will describe the adjustment means that the electronic device 100 may implement through different embodiments, but the specific design of the electronic device 100 is not limited to the following embodiments.

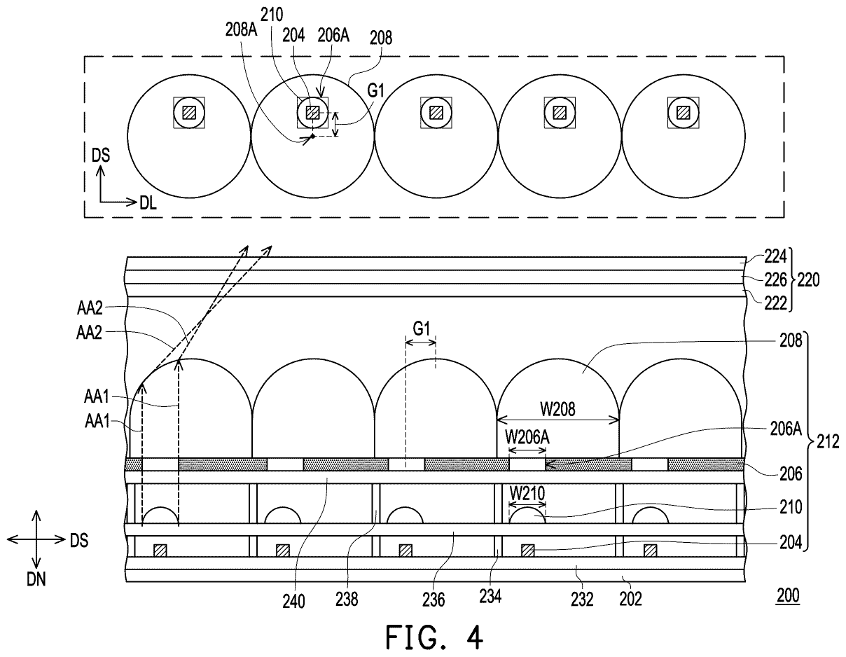

FIG. 4 is a partial schematic view of the electronic device according to an embodiment of the disclosure. An electronic device 200 may be considered as an implementation of the electronic device 100 in FIG. 1 to FIG. 3, and FIG. 4 mainly shows a partial cross-sectional schematic view of the electronic device 200 and an arrangement schematic view of some components (shown in the dashed box). Considering the adjustment of light travel, the electronic device 200 includes at least a substrate 202, a plurality of light-emitting elements 204, a light-shielding layer 206, a plurality of first lens units 208, and a plurality of second lens units 210. The light-emitting elements 204 are disposed on the substrate 202 and are adapted to provide light. In some embodiments, the substrate 202 may be a circuit board, but the disclosure is not limited thereto. In other embodiments, the substrate 202 may be a glass substrate with circuits. The light-emitting elements 204 may be light-emitting diodes, but the disclosure is not limited thereto. The light-shielding layer 206 is disposed on the light-emitting elements 204 and has a plurality of openings 206A, in which each opening 206A may correspond to one of the light-emitting elements 204. The plurality of first lens units 208 are disposed on the light-shielding layer 206 and correspond to the light-emitting elements 204. Additionally, the second lens units 210 are disposed between the light-shielding layer 206 and the light-emitting elements 204. In this embodiment, one of the light-emitting elements 204, one of the openings 206A of the light-shielding layer 206, one of the first lens units 208, and one of the second lens units 210 are stacked in the normal direction DN to form an anisotropic light-emitting structure 212 that can adjust the light traveling direction.

The light-emitting elements 204 may provide light in a direction away from the substrate 202. The light emitted from the light-emitting elements 204 first passes through the second lens units 210. The disposed position of the second lens units 210 may be aligned with the light-emitting elements 204 to concentrate (that is, to reduce the divergence angle of the light) the light emitted from the light-emitting elements 204. In some embodiments, a width W210 of the second lens units 210 may substantially correspond to (for example, equal to or slightly greater than) a width W206A of the openings 206A of the light-shielding layer 206. At the same time, the second lens units 210 may also be aligned with the openings 206A of the light-shielding layer 206 to allow the concentrated light to mainly project toward the openings 206A, which helps improve light utilization efficiency and may provide highly collimated light beams. In other words, in the electronic device 200, the light-emitting elements 204 may overlap the region of the openings 206A projected along the normal direction DN onto the substrate 202. Subsequently, the collimated light beams travel from the openings 206A toward the first lens units 208, as indicated by an arrow AA1. The space through which the light beams pass before and after passing through the first lens units 208 and the second lens units 210 may be air or a material with a refractive index smaller than the lens units.

In some embodiments, a width W208 of the first lens units 208 is greater than the width W206A of the openings 206A of the light-shielding layer 206 and greater than a width W210 of the second lens units 210. At the same time, each individual first lens unit 208 has a geometric center 208A. For example, if the bottom view structure of the first lens unit 208 is circular, then the geometric center 208A is the center of this circle. The openings 206A of the light-shielding layer 206 are spaced from the geometric center 208A of the corresponding first lens unit 208 by a distance G1. Here, the distance G1 may be the spacing between the geometric center of the openings 206A of the light-shielding layer 206 and the geometric center 208A of the corresponding first lens unit 208.

Under the arrangement of the second lens units 210 and the openings 206A, the light emitted from the light-emitting elements 204 is concentrated and projected onto a local arc surface structure of the first lens units 208 that is offset from the geometric center 208A. The arc surface structure of the first lens units 208 may refract the light to project toward a specific direction, as indicated by an arrow AA2, rather than uniformly projecting in all directions. As such, the electronic device 200 may establish images in a specific viewing angle region, thereby implementing the effect of viewing angle adjustment.

In some embodiments, the first lens units 208 may contact each other and connect together, but the disclosure is not limited thereto. In other embodiments, the first lens units 208 may be spaced apart from each other without contacting each other. Additionally, regardless of whether the first lens units 208 contact each other or are spaced apart from each other, each opening 206A of the light-shielding layer 206 may be completely covered by the corresponding first lens unit 208. In other words, in the top view structure, each opening 206A may be completely located within the area of the corresponding first lens unit 208.

FIG. 4 mainly presents the cross-sectional structure of several light-emitting elements 204 arranged along the short axis direction DS and the corresponding components thereof. For ease of explanation, the dashed box in FIG. 4 further presents the layout of the light-emitting elements 204, the openings 206A of the light-shielding layer 206, the first lens units 208, and the second lens units 210 along the long axis direction DL when viewed from the top-down direction (for example, the normal direction DN) of the electronic device 200. The top view structure in the dashed box shows that each light-emitting element 204 and each opening 206A of the light-shielding layer 206 are completely located within the area of the corresponding first lens unit 208 and outside the geometric center 208A of the corresponding first lens unit 208.

In the dashed box in FIG. 4, each light-emitting element 204 and each opening 206A of the light-shielding layer 206 are offset along the short axis direction DS with respect to the geometric center 208A of the corresponding first lens unit 208. When the structure of the electronic device 200 is implemented for the electronic device 100 in FIG. 1 to FIG. 3, the individual openings 206A of the light-shielding layer 206 may be positioned closer to the projection screen PP compared to the geometric center 208A of the corresponding first lens unit 208, causing the light from the light-emitting elements 204 to be emitted toward the projection screen PP generally along a travel path similar or equivalent to the display light L100. At this time, merely a small amount or almost none of the light from the light-emitting elements 204 is emitted toward other travel paths, thus the stray light X100 may be significantly less than the display light L100, thereby providing a good display effect with low glare.

In FIG. 4, the electronic device 200 further includes a display panel 220, and the display panel 220 may have two substrates 222 and 224 with a display layer 226 sandwiched between the two substrates 222 and 224. In some embodiments, the display layer 226 may include an optical medium layer, such as liquid crystal, electrophoretic particles, or other materials whose optical performance may be controlled by electricity, but the disclosure is not limited thereto. Both substrate 222 and substrate 224 are transparent substrates, and the display panel 220 may be a transmissive display panel. The display panel 220 is disposed on the first lens units 208 to convert the light emitted from the first lens units 208 into display light carrying display information (such as the display light L100 in FIG. 1 and FIG. 2). Here, the components disposed below the display panel 220 may be considered as a backlight module, and according to the above description, the backlight module at least includes the substrate 202 and multiple anisotropic light-emitting structures 212 formed by multiple light-emitting elements 204, the light-shielding layer 206, multiple first lens units 208, and multiple second lens units 210. The backlight module may further include other functional films, such as diffusion films, prism films, support films, or heat dissipation films, but the disclosure is not limited thereto.

In some embodiments, the electronic device 200 (or the backlight module of the electronic device 200) may further include a reflection layer 232 disposed on the substrate 202. The light-emitting elements 204 may be disposed on the reflection layer 232. The reflection layer 232 may reflect the light emitted from the light-emitting elements 204 to travel toward the direction of the light-shielding layer 206 as much as possible. The electronic device 200 may further include a support structure 234 and a support layer 236. The second lens units 210 may be disposed on the support layer 236, and the support structure 234 is disposed between the substrate 202 and the support layer 236. The support structure 234 is used to separate the support layer 236 and the light-emitting elements 204 by an appropriate distance to allow the second lens units 210 to provide an ideal collimation effect. For example, the distance by which the support structure 234 separates the support layer 236 from the light-emitting elements 204 may allow the light-emitting surface of the light-emitting elements 204 to be located at the focus of the second lens units 210. In some embodiments, the sidewalls of the support structure 234 may have reflective properties to reflect the light emitted from the light-emitting elements 204 to travel toward the direction of the light-shielding layer 260 as much as possible, which helps improve light utilization efficiency. In some embodiments, the sidewalls of the support structure 234 may be inclined with respect to the normal direction DN. For example, the support structure 234 may be a reflective cup.

The electronic device 200 may further include a support structure 238 and a support layer 240. The light-shielding layer 206 may be disposed on the support layer 240, and the support structure 238 is disposed between the support layer 240 and the support layer 236. The support structure 238 may separate the light-shielding layer 206 from the second lens units 210, while the support layer 240 is used to carry the light-shielding layer 206. The support structure 238 may be disposed corresponding to the support structure 234 to allow light emitted from the individual light-emitting elements 204 to travel toward the corresponding openings 206A. In some embodiments, the sidewalls of the support structure 238 may have reflective properties to reflect the light to travel toward the corresponding openings 206A of the light-shielding layer 260 as much as possible, which helps improve light utilization efficiency. In addition, the support structure 234 and the support structure 238 help reduce the light emitted from each light-emitting element 204 from traveling at an oblique angle toward more distant openings 206A.

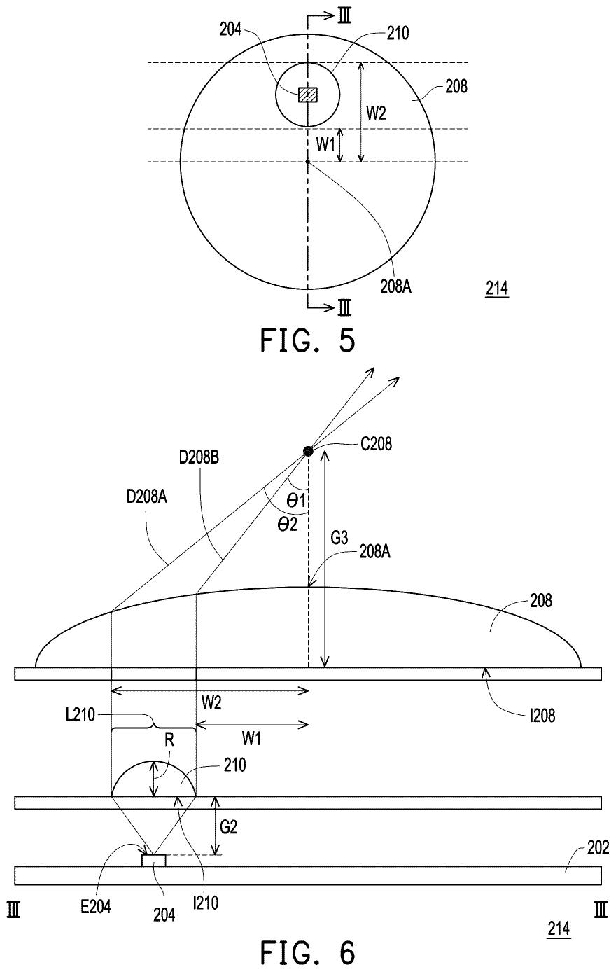

FIG. 5 and FIG. 6 are used to illustrate another implementation of a single anisotropic light-emitting structure. The components in FIG. 5 and FIG. 6 use the same reference numerals as in FIG. 4, and may be understood as the same components. An anisotropic light-emitting structure 214 in FIG. 5 and FIG. 6 includes a light-emitting element 204, a first lens unit 208, and a second lens unit 210. FIG. 5 shows a top view structure of the anisotropic light-emitting structure 214, and FIG. 6 shows a cross-sectional structure along a line III-III in FIG. 5, where the line III-III crosses the geometric center 208A of the first lens unit 208. In some embodiments, as shown in FIG. 5, in the top view direction of the electronic device, the light-emitting element 204 may overlap with the geometric center of the second lens unit 210, while the position of the second lens unit 210 is offset with respect to the geometric center 208A of the first lens unit 208 along the extension direction of the line III-III. The minimum distance between the geometric center 208A (for example, the center of the circle) of the first lens unit 208 and the second lens unit 210 is a distance W1, and the maximum distance between the geometric center 208A of the first lens unit 208 and the second lens unit 210 is a distance W2. Both distance W1 and distance W2 are less than ½ of the width of the first lens unit 208. In some embodiments, the contours of the first lens unit 208 and the second lens unit 210 may be circular or elliptical, but the disclosure is not limited thereto.

As shown in FIG. 6, a spacing distance G2 between a light exit surface E204 of the light-emitting element 204 and a light entry surface 1210 of the second lens unit 210 may be approximately the focal length of the second lens unit 210, and the light exit surface E204 of the light-emitting element 204 may be located at the focus of the second lens unit 210. In some embodiments, the spacing distance G2 may be 0.8 to 1.2 times the focal length of the second lens unit 210. As a result, the light emitted from the light-emitting element 204 becomes a collimated light beam L210 through the effect of the second lens unit 210, and travels toward the first lens unit 208 in a substantially collimated manner. Since the second lens unit 210 is offset with respect to the geometric center 208A of the first lens unit 208, the collimated light beam L210 is directed onto a local arc surface structure of the first lens unit 208 and be deflected.

For example, the traveling direction of the collimated beam L210 after being deflected by the first lens unit 208 may generally be confined between a first deflection direction D208A and a second deflection direction D208B. The first deflection direction D208A and the second deflection direction D208B intersect at a focal point C208 of the first lens unit 208, where a distance G3 from the focal point C208 to a light entrance surface 1208 of the first lens unit 208 may be approximately equal to the focal length of the first lens unit 208. The first deflection direction D208A forms a first deflection angle θ1 with the central axis of the first lens unit 208, and the second deflection direction D208B forms a second deflection angle θ2 with the central axis of the first lens unit 208. An angular range between the first deflection angle θ1 and the second deflection angle θ2 is the angular range of the displayed light. The first deflection angle θ1, the distance W1, and the distance G3 satisfy the following equation:

$$tan ( θ 1 ) = \frac{W 1}{G 3} ,$$

and the second deflection angle θ2, the distance W2, and the distance G3 satisfy the following equation:

$$tan ( θ 2 ) = \frac{W 2}{G 3} .$$

Therefore, the first deflection angle θ1 and the second deflection angle θ2 can be adjusted by the distances W1, W2, and G3, thereby obtaining the angular range required for the displayed light, which provides the desired display effect.

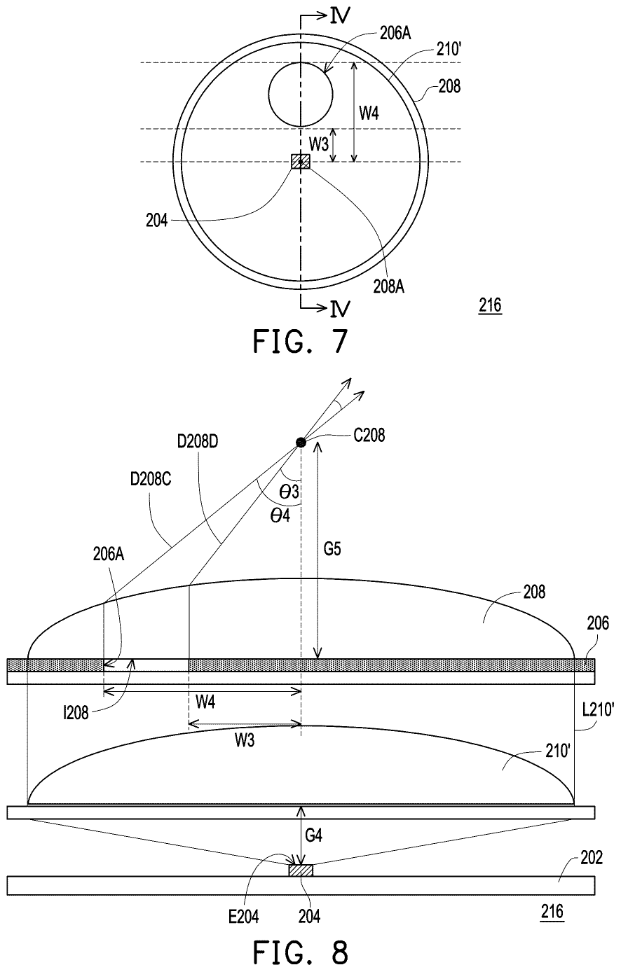

FIG. 7 and FIG. 8 are used to illustrate another implementation of a single anisotropic light-emitting structure. The components in FIG. 7 and FIG. 8 use the same reference numerals as in FIG. 4, and may be understood as the same components. An anisotropic light-emitting structure 216 in FIG. 7 and FIG. 8 includes a light-emitting element 204 disposed on a substrate 202, a light-shielding layer 206 disposed on the light-emitting element 204 and having an opening 206A, a first lens unit 208 disposed on the light-shielding layer 206, and a second lens unit 210′ disposed between the light-shielding layer 206 and the light-emitting element 204. FIG. 7 shows a top view structure of the anisotropic light-emitting structure 216, and FIG. 8 shows a cross-sectional structure along a line IV-IV in FIG. 7, where the line IV-IV crosses the geometric center 208A of the first lens unit 208. In some embodiments, as shown in FIG. 7, the geometric center of the second lens unit 210′ may overlap with the geometric center of the first lens unit 208, and in the top view direction of the electronic device, the light-emitting element 204 overlaps with the geometric center of the second lens unit 210′. The position of the opening 206A of the light-shielding layer 206 is offset along the extension direction of the line IV-IV with respect to the geometric center of the first lens unit 208. For example, the minimum distance between the geometric center (for example, the center of the circle in the top view structure) of the first lens unit 208 and the opening 206A is a distance W3, and the maximum distance between the geometric center of the first lens unit 208 and the opening 206A is a distance W4. Both distance W3 and distance W4 are less than ½ of the width (for example, the radius in the top view structure) of the first lens unit 208. In some embodiments, both the first lens unit 208 and the second lens unit 210′ have circular contours and share the same center, but the area of the first lens unit 208 is larger than the area of the second lens unit 210′. For example, in FIG. 7, the second lens unit 210′ is completely located within the area of the first lens unit 208, but the disclosure is not limited thereto.

As shown in FIG. 8, a spacing distance G4 between the light exit surface E204 of the light-emitting element 204 and a light entry surface 1210′ of the second lens unit 210′ may be substantially equal to the focal length of the second lens unit 210′, thus the light exit surface E204 of the light-emitting element 204 may be located at the focus of the second lens unit 210. As a result, the light emitted from the light-emitting element 204 becomes a collimated light beam L210′ through the effect of the second lens unit 210, and travels toward the light-shielding layer 206 in a substantially collimated manner before being emitted through the opening 206A of the light-shielding layer 206. Since the opening 206A is offset with respect to the geometric center 208A of the first lens unit 208, the collimated light beam L210′ is directed onto the local arc surface structure of the first lens unit 208 and be deflected.

For example, part of the collimated beam L210′ emitted from the opening 206A, after being deflected by the first lens unit 208, may have the traveling direction thereof confined between a first deflection direction D208C and a second deflection direction D208D. The first deflection direction D208C and the second deflection direction D208D intersect at the focal point C208 of the first lens unit 208, where a distance G5 from the focal point C208 to the light entrance surface 1208 of the first lens unit 208 may be approximately equal to the focal length of the first lens unit 208. The first deflection direction D208C forms a first deflection angle θ3 with the central axis of the first lens unit 208, and the second deflection direction D208D forms a second deflection angle θ4 with the central axis of the first lens unit 208. Here, the first deflection angle θ3 and the second deflection angle θ4 can be adjusted by the distances W3, W4, and G5, where the first deflection angle θ3, the distance W3, and the distance G5 satisfy the following equation:

$$tan ( θ 3 ) = \frac{W 3}{G 5} ,$$

and the second deflection angle θ4, the distance W4, and the distance G5 satisfy the following equation:

$$tan ( θ 4 ) = \frac{W 4}{G 5} .$$

Therefore, the designer may set the distances W3, W4, and G5 based on the first deflection angle θ3 and the second deflection angle θ4 required for the displayed light, which provides the desired display effect.

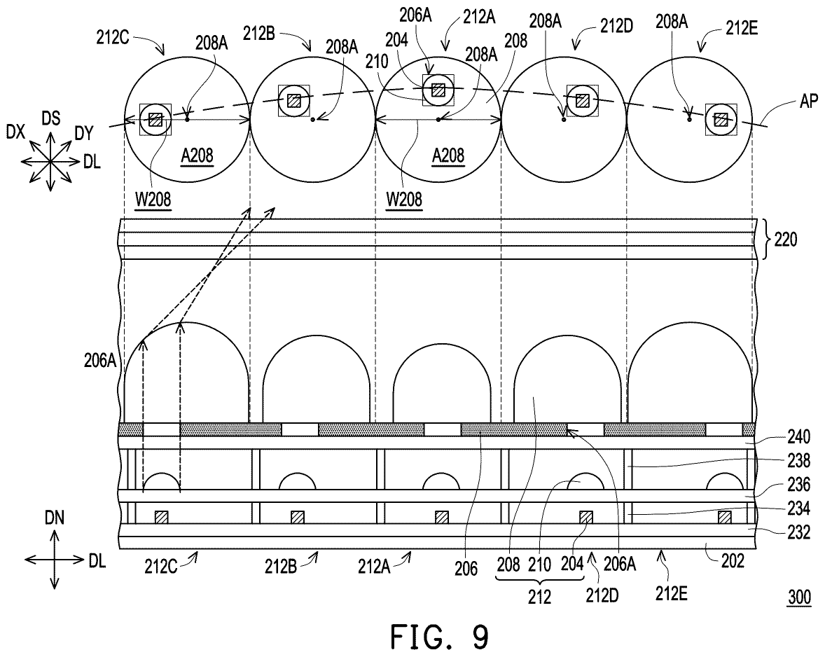

FIG. 9 is a partial schematic view of the electronic device according to an embodiment of the disclosure. The components in FIG. 9 use the same reference numerals as in FIG. 4 to represent the same or equivalently substitutable components. However, the layout arrangement of some components in FIG. 9 differs from that in FIG. 4. An electronic device 300 in FIG. 9 includes a substrate 202, multiple anisotropic light-emitting structures 212 disposed on the substrate 202, and a display panel 220. In addition, the electronic device 300 also includes the reflection layer 232, the support structure 234, the support layer 236, the support structure 238, and the support layer 240 already explained in FIG. 4 to assemble the multiple anisotropic light-emitting structures 212 into a backlight module. FIG. 9 mainly presents the cross-sectional structure of the individual anisotropic light-emitting structures 212 cut along the long axis direction DL with the cutting line passing through the corresponding light-emitting element 204. Additionally, for ease of explanation, FIG. 9 presents the corresponding top view structure (that is, the structure presented when viewing the electronic device 300 along the normal direction DN) above each anisotropic light-emitting structure 212.

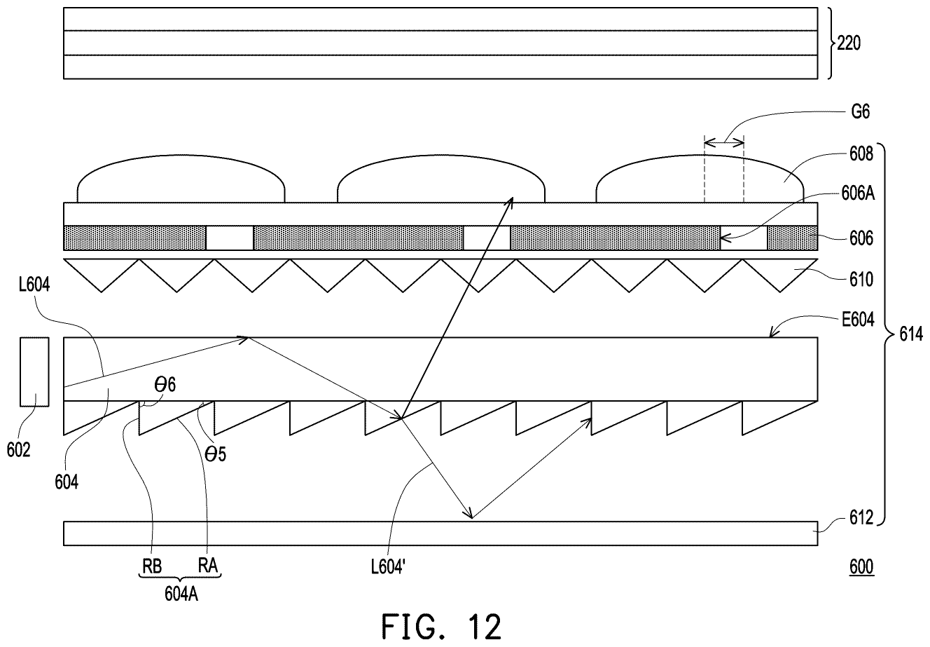

As described in FIG. 4, each individual anisotropic light-emitting structure 212 may include a light-emitting element 204 disposed on the substrate 202, a light-shielding layer 206 with an opening 206A disposed on the light-emitting element 204, a first lens unit 208 disposed on the light-shielding layer 206, and a second lens unit 210 disposed between the light-emitting element 204 and the opening 206A of the light-shielding layer 206. For ease of explanation, the multiple anisotropic light-emitting structures 212 shown in FIG. 12 are connected to each other, but in reality, the anisotropic light-emitting structures 212 may be dispersed at different locations in the electronic device 300 without contacting each other.

Additionally, the disposed positions of the multiple openings 206A of the light-shielding layer 206 with respect to the first lens unit 208 are different among the multiple anisotropic light-emitting structures 212 shown in FIG. 9. For ease of explanation, anisotropic light-emitting structures 212A to 212E are used here to represent different arrangement methods of the anisotropic light-emitting structures 212. In each of the anisotropic light-emitting structures 212A to 212E, the light-emitting element 204, the corresponding opening 206A of the light-shielding layer 206, and the second lens unit 210 are, for example, aligned with each other.

Additionally, in each of the anisotropic light-emitting structures 212A to 212E, the light-emitting element 204, the corresponding opening 206A of the light-shielding layer 206, and the second lens unit 210 are all located within the area of the first lens unit 208 in the top view structure. However, in different anisotropic light-emitting structures 212A to 212E, the light-emitting element 204, the corresponding opening 206A of the light-shielding layer 206, and the second lens unit 210 present different relationships with respect to the geometric center 208A of the first lens unit 208. In some embodiments, when viewed from the top view structure of the anisotropic light-emitting structures 212A to 212E, the openings 206A of the light-shielding layer 206 may be arranged along an arrangement path AP of curved arc shape. In some embodiments, from the top view structure of the anisotropic light-emitting structures 212A to 212E, the openings 206A of the light-shielding layer 206 may correspond to different positions of the display panel 220.

As shown in the top view structure and cross-sectional structure in FIG. 9, the opening 206A of the light-shielding layer 206 in the anisotropic light-emitting structure 212A is generally offset from the geometric center 208A of the first lens unit 208 in the short axis direction DS. The cross-sectional structure of the anisotropic light-emitting structure 212A cut along the long axis direction DL through the light-emitting element 204 does not pass through the geometric center 208A of the first lens unit 208. Therefore, the first lens unit 208 in the cross-sectional structure of the anisotropic light-emitting structure 212A has a narrower width and smaller height compared to the first lens unit 208 of other anisotropic light-emitting structures 212B to 212D. In some embodiments, from the top view structure of the anisotropic light-emitting structures 212A to 212E, the anisotropic light-emitting structures 212A to 212E may correspond to different positions of the display panel 220.

The anisotropic light-emitting structure 212B is, for example, disposed at one side of the anisotropic light-emitting structure 212A in the long axis direction DL. From the top view structure, the opening 206A of the light-shielding layer 206 in the anisotropic light-emitting structure 212B is offset from the geometric center 208A of the corresponding first lens unit 208 in an inclined direction DX. The inclined direction DX may intersect both the short axis direction DS and the long axis direction DL. The cross-sectional structure of the anisotropic light-emitting structure 212A cut along the long axis direction DL through the light-emitting element 204 does not pass through the geometric center 208A of the first lens unit 208. At the same time, the cross-sectional structure of the anisotropic light-emitting structure 212B cut along the long axis direction DL through the light-emitting element 204 is closer to the geometric center 208A of the corresponding first lens unit 208 compared to the cross-sectional structure of the anisotropic light-emitting structure 212A cut along the long axis direction DL through the light-emitting element 204. As such, the cross-sectional structure of the first lens unit 208 of the anisotropic light-emitting structure 212B shown in FIG. 9 has a wider width and greater height than the first lens unit 208 of the anisotropic light-emitting structure 212A. Specifically, one of the openings 206A of the light-shielding layer 206 is spaced from the geometric center 208A of a corresponding first lens unit 208 by a distance in a first direction (for example, the design of the anisotropic light-emitting structure 212A), another opening 206A of the light-shielding layer 206 is spaced from the geometric center 208A of another corresponding first lens unit 208 by a distance in a second direction (for example, the design of the anisotropic light-emitting structure 212B), and the first direction is different from the second direction.

The anisotropic light-emitting structure 212C is, for example, disposed at one side of the anisotropic light-emitting structure 212A in the long axis direction DL, and the anisotropic light-emitting structure 212C is farther away from the anisotropic light-emitting structure 212A than the anisotropic light-emitting structure 212B. From the top view structure, the opening 206A of the light-shielding layer 206 in the anisotropic light-emitting structure 212C is offset from the geometric center 208A of the corresponding first lens unit 208 in the long axis direction DL. The cross-sectional structure of the anisotropic light-emitting structure 212A, for example, passes through the geometric center 208A of the first lens unit 208. As such, in FIG. 9, the first lens unit 208 of the anisotropic light-emitting structure 212C has a wider width and greater height than the first lens unit 208 of the anisotropic light-emitting structure 212B. However, from the top view structure, it may be seen that the first lens units 208 of the anisotropic light-emitting structures 212A to 212E may have substantially the same size. In some embodiments, the first lens units 208 of at least two anisotropic light-emitting structures 212A to 212E may have different sizes. For example, in the top view direction (for example, the normal direction DN), a projection area A208 of the first lens unit 208 of the anisotropic light-emitting structure 212A may be different in size from a projection area A208 of the first lens unit 208 of the anisotropic light-emitting structure 212C. Alternatively, for example, the width W208 of the first lens unit 208 of the anisotropic light-emitting structure 212A in the long axis direction DL may be different from the width W208 of the first lens unit 208 of the anisotropic light-emitting structure 212C in the long axis direction DL.

The anisotropic light-emitting structure 212D and the anisotropic light-emitting structure 212E are, for example, disposed at another side of the anisotropic light-emitting structure 212A in the long axis direction DL, and the anisotropic light-emitting structure 212E is farther away from the anisotropic light-emitting structure 212A than the anisotropic light-emitting structure 212D. The opening 206A of the light-shielding layer 206 in the anisotropic light-emitting structure 212D is offset from the geometric center 208A of the corresponding first lens unit 208 in the inclined direction DY. The inclined direction DY may intersect both the short axis direction DS and the long axis direction DL, and the inclined direction DY and the inclined direction DX may be at different sides of the short axis direction DS and also at different sides of the long axis direction DL. In some embodiments, an included angle between the inclined direction DY and the short axis direction DS may be substantially equal to an included angle between the inclined direction DX and the short axis direction DS, or an included angle between the inclined direction DY and the long axis direction DL may be substantially equal to an included angle between the inclined direction DX and the long axis direction DY, but the disclosure is not limited thereto. Additionally, the opening 206A of the light-shielding layer 206 in the anisotropic light-emitting structure 212E is offset from the geometric center 208A of the corresponding first lens unit 208 in the long axis direction DL.

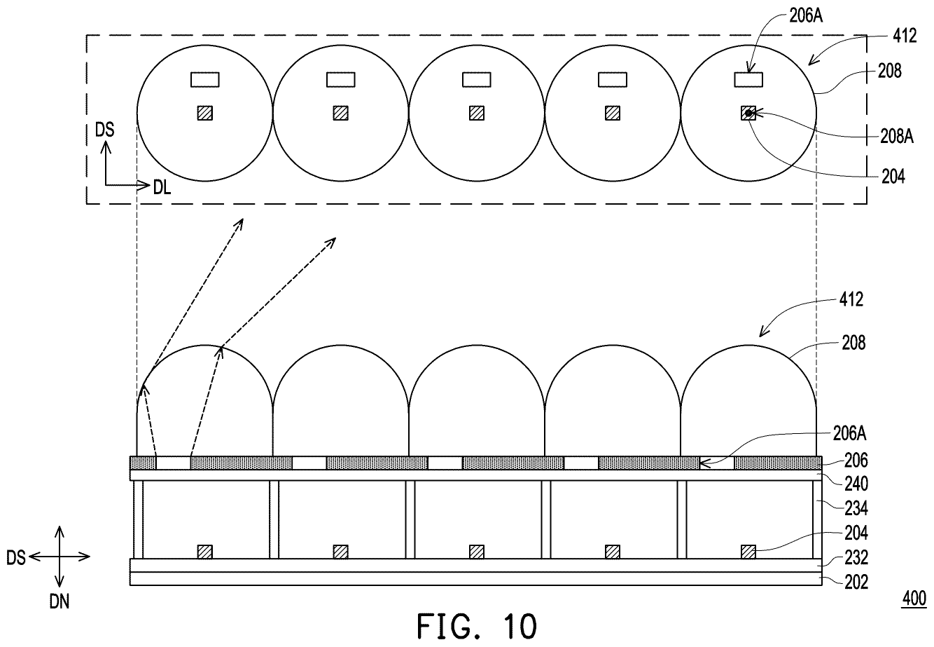

FIG. 10 is a schematic view of the electronic device according to an embodiment of the disclosure. The components in FIG. 10 use the same reference numerals as in FIG. 4 to represent components that provide the same or equivalently substitutable functions. However, the embodiment in FIG. 10 omits the display panel 220 in FIG. 4 and merely presents the related components of the backlight module. The electronic device 400 in FIG. 10 includes a substrate 202, a plurality of light-emitting elements 204 disposed on the substrate 202, a light-shielding layer 206 having a plurality of openings 206A disposed on the light-emitting elements 204, and a plurality of first lens units 208 disposed on the light-shielding layer 206. Compared with the embodiment in FIG. 4, in the electronic device 400 in FIG. 10, lens units or similar structures may not be disposed between the light-emitting elements 204 and the light-shielding layer 206. Additionally, the electronic device 400 may further include the reflection layer 232 disposed on the substrate 202 as described in FIG. 4, the support structure 234 disposed on the substrate 202 and located around the light-emitting elements 204, and the support layer 240 carrying the light-shielding layer 206. The support structure 234 may extend between the support layer 240 and the reflection layer 232, so that the light-emitting elements 204 is spaced from the light-shielding layer 206 by a certain distance.

In FIG. 10, each light-emitting element 204, the corresponding opening 206A in the light-shielding layer 260, and the corresponding first lens unit 208 may form an anisotropic light-emitting structure 412. For convenience of explanation, FIG. 10 presents cross-sectional structures of five anisotropic light-emitting structures 412 arranged along the short axis direction DS, and the dashed box in FIG. 10 presents top view structures of five anisotropic light-emitting structures 412 arranged along the long axis direction DL. In each anisotropic light-emitting structure 412, the light-emitting element 204 may be located at the geometric center 208A of the first lens unit 208, while the opening 206A of the light-shielding layer 206 may be offset with respect to the geometric center 208A of the first lens unit 208 in the short axis direction DS, but the disclosure is not limited thereto. In some alternative embodiments, the opening 206A of the light-shielding layer 206 may be offset with respect to the geometric center 208A of the first lens unit 208 in other directions not limited to the short axis direction DS. Additionally, as shown in the top view structure, the light-emitting elements 204 and the corresponding openings 206A in the light-shielding layer 206 in the electronic device 400 are not aligned with each other.

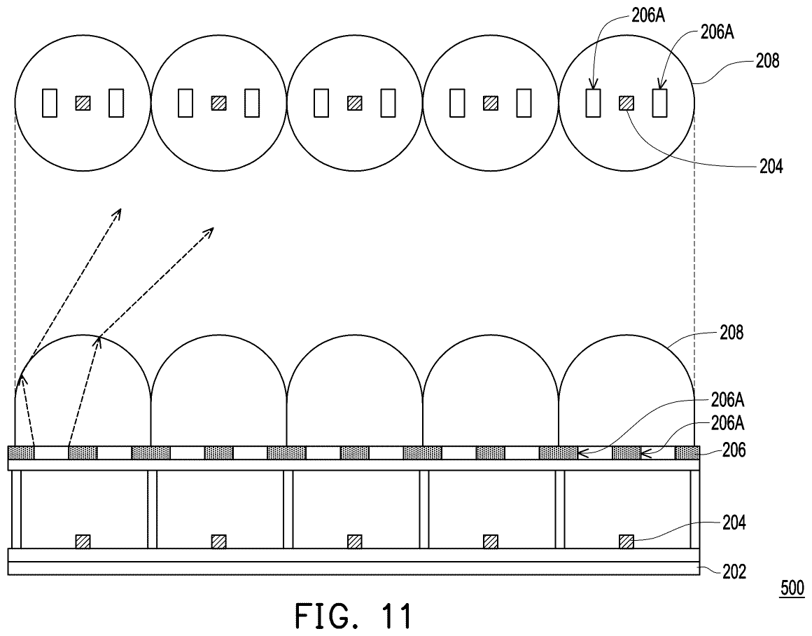

FIG. 11 is a schematic view of the electronic device according to an embodiment of the disclosure. The components in FIG. 11 use the same reference numerals as in FIG. 10 to represent components that provide the same or equivalently substitutable functions. An electronic device 500 in FIG. 10 includes a substrate 202, a plurality of light-emitting elements 204 disposed on the substrate 202, a light-shielding layer 206 having openings 206A disposed on the light-emitting elements 204, and a plurality of first lens units 208 disposed on the light-shielding layer 206. In the electronic device 500, two openings 206A may correspond to the same light-emitting element 204. Furthermore, as shown in the top view structure in FIG. 11, the two openings 206A may be at opposite sides of the corresponding single light-emitting element 204. The two openings 206A may guide light to travel toward different viewing angle regions, thereby providing images for viewers at different positions. When the electronic device 500 is applied to a vehicle head-up display, the two separate openings 206A may implement a display effect that provides images to both the driver and the passenger next to the driver.

FIG. 12 is a partial cross-sectional structural schematic view of the electronic device according to an embodiment of the disclosure. An electronic device 600 in FIG. 12 may be applied in the installation environment of the electronic device 100 in FIG. 1, and may have the same external contour design as the electronic device 100. The electronic device 600 includes a backlight module 614 formed by light-emitting elements 602, a light guide plate 604, a light-shielding layer 606, a plurality of lens units 608, a light control film 610, a reflection layer 612, and a display panel 220 located above the backlight module 614, in which the display panel 220 may refer to the relevant description of FIG. 4.

In the backlight module 614, the light-emitting elements 602 are located at the side of the light guide plate 604. The light-shielding layer 606 is disposed on the light guide plate 604, and the plurality of lens units 608 are disposed on the light-shielding layer 606. Additionally, the light control film 610 is disposed between the light-shielding layer 606 and the light guide plate 604, and the light guide plate 604 is disposed between the light control film 610 and the reflection layer 612. In some embodiments, the light control film 610 may have a prism structure, an arc surface structure, or a high blocking wall structure, or a combination thereof, but the disclosure is not limited thereto.

The light-emitting elements 602 emit light toward the side of the light guide plate 604. The light guide plate 604 has a plurality of guiding structures 604A to guide and disperse light L604 entering the light guide plate 604 throughout the entire plate body and emit the light from the light exit surface E604 of the light guide plate 604. In other words, the light guide plate 604 is a side-entry light guiding component. In some embodiments, the guiding structures 604A may be structures protruding toward the reflection layer 612, formed by a guiding bevel RA and a guiding bevel RB. The guiding bevel RA and the guiding bevel RB are not symmetrical to each other, which helps adjust the traveling direction of the light L604, so that the light L604 leaves the light guide plate 604 at a more collimated angle. In each protruding guiding structure 604A, the guiding bevel RA is farther from the light-emitting elements 602 than the guiding bevel RB, and the guiding bevel RA is more inclined than the guiding bevel RB. In some embodiments, the light L604 traveling in the light guide plate 604 may leave the light guide plate 604 at the guiding bevel RA and become leaked light L604′. At this time, the reflection layer 612 may reflect the light L604′ to re-enter the light guide plate 604, which helps improve the light utilization efficiency.

In individual guiding structures 604A, the guiding bevel RA and the guiding bevel RB may form a first included angle θ5 and a second included angle θ6 with the bottom surface, respectively. The angular sizes of the first included angle θ5 and the second included angle θ6 may affect the traveling angular range of the display light of the electronic device 600. When the electronic device 600 is applied to the installation condition in FIG. 1, in some embodiments, the first included angle θ5 may generally fall within the range of 9 degrees to 37 degrees, and the second included angle θ6 may generally fall within the range of 80 degrees to 95 degrees, which helps reduce the stray light X100, so that the light provided by the electronic device 600 is mainly used to establish images for viewers. In some embodiments, optionally, the first included angle θ5 may generally fall within the range of 14 degrees to 32 degrees, and the second included angle θ6 may generally fall within the range of 85 degrees to 89 degrees.

The light control film 610 located above the light guide plate 604 may have a plurality of prismatic protruding structures to provide the function of collimating light. Thus, the light emitted from the light guide plate 604 can travel in a collimated manner through the opening 606A and be directed onto the lens unit 608 after passing through the light control film 610. Similar to the foregoing embodiments, the center of the opening 606A is spaced from the geometric center of the corresponding lens unit 608A by a distance G6, so that under the arc surface structure of the lens unit 608A, the backlight module 614 may provide light toward a specific angular range and provide significantly less light or almost no light in other angular ranges. The light provided by the backlight module 614 may be transformed into display light carrying display information after passing through the display panel 220, thereby implementing the display function of the head-up display.

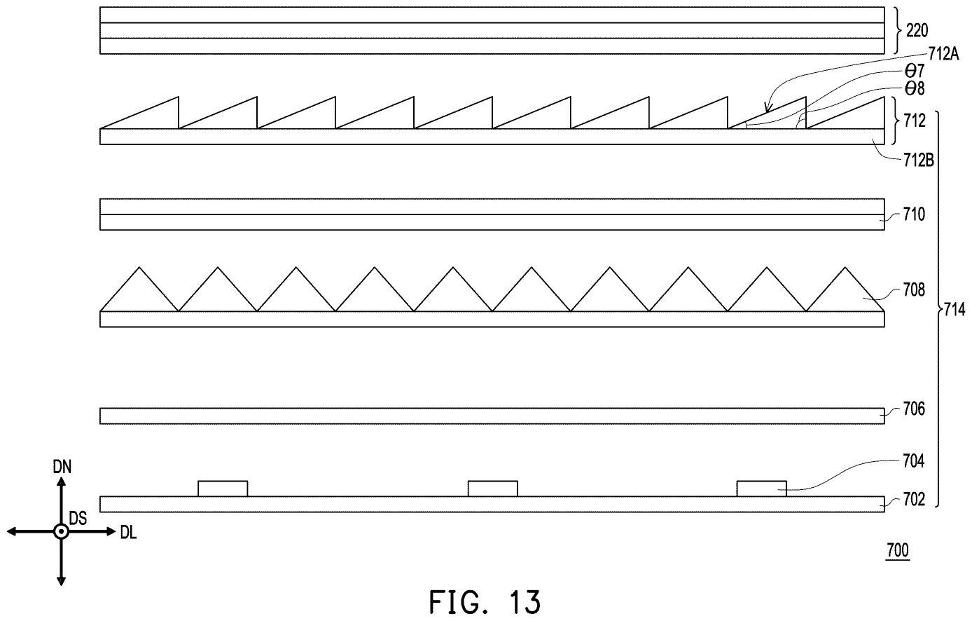

FIG. 13 is a partial cross-sectional structural schematic view of the electronic device according to an embodiment of the disclosure. An electronic device 700 includes a backlight module 714 formed by a substrate 702, a plurality of light-emitting elements 704, a diffusion film 706, a first brightness enhancement film 708, a second brightness enhancement film 710, and a prism sheet 712 sequentially stacked in the normal direction DN as described in FIG. 1. The electronic device 700 further includes a display panel 220 disposed above the backlight module 714, in which the display panel 220 may refer to the description of FIG. 4, so details will not be repeated here.

The plurality of light-emitting elements 704 are disposed on the substrate 702 and emit light in a direction away from the substrate 702. The diffusion film 706 is disposed on the light-emitting elements 704, and may be used to diffuse light from the light-emitting elements 704, making the light distribution more uniform. The first brightness enhancement film 708 and the second brightness enhancement film 710 have parallel protruding structures extending along different directions, with which to concentrate light from the diffusion film 706 into a smaller divergence angle, achieving the effect of enhancing brightness. In some embodiments, the protruding structures of the first brightness enhancement film 708 may be parallel to the short axis direction DS, and the protruding structures of the second brightness enhancement film 710 may be parallel to the long axis direction DL. In some embodiments, the extension direction of the protruding structures of at least one of the first brightness enhancement film 708 and the second brightness enhancement film 710 may intersect both the long axis direction DL and the short axis direction DS. The extension direction of the protruding structures inclined at a small angle (for example, 0.1 degrees to 5 degrees, or 4 degrees or less) helps reduce interference phenomena (such as moiré patterns) caused by the regular arrangement of structural features of different components. The extension direction of the protruding structures inclined at a larger angle (for example, 4 degrees to 20 degrees) helps direct light to emit at a specific angular range to achieve the effect of displaying images in a limited region. In some other embodiments, the protruding structures of at least one of the first brightness enhancement film 708 and the second brightness enhancement film 710 may be arranged such that protruding structures at different positions have different extension directions. In some other embodiments, the electronic device 700 may omit the second brightness enhancement film 710 and merely retain the first brightness enhancement film 708.

Light emitted from the light-emitting elements 704, after passing through the diffusion film 706, the first brightness enhancement film 708, and the second brightness enhancement film 710, may enter the prism sheet 712 in a substantially collimated traveling direction. The prism sheet 712 may include a plurality of prism structures 712A and a support layer 712B carrying the prism structures 712A. Individual prism structures 712A include two bevels and a bottom surface connecting between the two bevels, and the two bevels may form a first included angle θ7 and a second included angle θ8 with the bottom surface, respectively. The angular sizes of the first included angle θ7 and the second included angle θ8 may affect the traveling angular range of the display light of the electronic device 700. When the electronic device 700 is applied to the installation condition in FIG. 1, in some embodiments, the first included angle θ7 may generally fall within the range of 9 degrees to 37 degrees, and the second included angle θ8 may generally fall within the range of 80 degrees to 95 degrees, which helps reduce stray the light X100, so that the light provided by the electronic device 700 is mainly used to establish images for viewers. In some embodiments, optionally, the first included angle θ7 may generally fall within the range of 14 degrees to 32 degrees, and the second included angle θ8 may generally fall within the range of 85 degrees to 89 degrees.

In summary, the electronic device of the embodiments of the disclosure may direct the light emitted from the light-emitting elements mainly toward a specific angular range through means such as lens structures, light-shielding structures, prism structures, and blocking wall structures. Therefore, the electronic device may provide images within a specific angular range, and light leakage outside the specific angular range may be reduced, thereby achieving the desired display effect with a limited viewing angle. The electronic device of the embodiments of the disclosure may be applied not only to head up display technology but also to privacy protection, three-dimensional display, realistic display, and other technologies.

What is claimed is:

1. An electronic device, comprising:
a substrate;
a plurality of light-emitting elements disposed on the substrate;
a light-shielding layer disposed on the plurality of light-emitting elements and having a plurality of openings; and
a plurality of lens units disposed on the light-shielding layer and corresponding to the plurality of light-emitting elements, wherein in a top view direction of the electronic device, each of the plurality of lens units has a geometric center, and one of the plurality of openings of the light-shielding layer is spaced from the geometric center of a corresponding one of the plurality of lens units by a distance.

2. The electronic device as claimed in claim 1, wherein the one of the plurality of openings of the light-shielding layer is spaced from the geometric center of the corresponding one of the plurality of lens units in a first direction, another one of the plurality of openings of the light-shielding layer is spaced from the geometric center of another corresponding one of the plurality of lens units in a second direction, and the first direction is different from the second direction.

3. The electronic device as claimed in claim 1, wherein in the top view direction of the electronic device, the plurality of light-emitting elements overlap with the geometric centers of the plurality of lens units.

4. The electronic device as claimed in claim 1, wherein each of the plurality of light-emitting elements overlaps with a region of the plurality of openings of the light-shielding layer projected onto the substrate.

5. The electronic device as claimed in claim 1, wherein in the top view direction of the electronic device, one of the plurality of openings of the light-shielding layer is located within an area of the corresponding one of the plurality of lens units.

6. The electronic device as claimed in claim 1, wherein the electronic device has an elongated contour, and two edges on opposite sides of the electronic device in a short axis direction are curved.

7. The electronic device as claimed in claim 6, wherein the two edges on the opposite sides of the electronic device in the short axis direction have different radii of curvature.

8. The electronic device as claimed in claim 1, wherein the electronic device has a top surface and a bottom surface, and the top surface and the bottom surface are curved.

9. The electronic device as claimed in claim 1, wherein the plurality of openings of the light-shielding layer are arranged along an arrangement path of curved arc shape.

10. The electronic device as claimed in claim 1, wherein the plurality of openings of the light-shielding layer have asymmetric contours.

11. The electronic device as claimed in claim 1, wherein the plurality of lens units have different widths.

12. The electronic device as claimed in claim 1, further comprising a plurality of second lens units disposed between the light-shielding layer and the plurality of light-emitting elements.

13. The electronic device as claimed in claim 12, wherein in the top view direction of the electronic device, one of the plurality of openings of the light-shielding layer, one of the plurality of light-emitting elements, one of the plurality of lens units, and one of the plurality of second lens units are stacked.

14. The electronic device as claimed in claim 12, wherein one of the plurality of second lens units is aligned with one of the plurality of openings of the light-shielding layer.

15. The electronic device as claimed in claim 12, wherein one of the plurality of second lens units is aligned with one of the plurality of lens units.

16. The electronic device as claimed in claim 12, further comprising a support structure, separating the light-shielding layer from the plurality of second lens units.

17. The electronic device as claimed in claim 1, further comprising a support structure, separating the light-shielding layer from the plurality of light-emitting elements.

18. The electronic device as claimed in claim 1, wherein two of the plurality of openings of the light-shielding layer correspond to one of the plurality of light-emitting elements.

19. The electronic device as claimed in claim 18, wherein the two of the plurality of openings of the light-shielding layer are located on both sides of the one of the plurality of light-emitting elements.

20. The electronic device as claimed in claim 1, further comprising a plurality of light-blocking structures, respectively corresponding to and surrounding one of the plurality of light-emitting elements.
